(19) United States
(12) Patent Application Publication
(10) Pub. No.: US 2010/0112780 A1
(43) Pub. Date: May 6, 2010

(54) Microwave-Induced Ion Cleaving and Patternless Transfer of Semiconductor Films

(75) Inventors: Douglas C. Thompson, Chandler, AZ (US); James W. Mayer, Phoenix, AZ (US); Michael Nastasi, Santa Fe, NM (US); Terry L. Alford, Phoenix, AZ (US)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: The Arizona Board of Regents, a body corporate acting on behalf of Arizona State University, Tempe (AZ)

(21) Appl. No.: 11/995,295

(22) PCT Filed: Jul. 11, 2006
(86) PCT No.: PCT/US2006/026886

§ 371 Date: Jan. 11, 2010

Related U.S. Application Data
(60) Provisional application No. 60/698,309, filed on Jul. 12, 2005.
(60) Provisional application No. 60/700,567, filed on Jul. 19, 2005.

(51) Int. Cl. H01L 21/18

(52) U.S. Cl. 438/458; 257/E21.087

(57) ABSTRACT

A method of ion cleaving using microwave radiation is described. The method includes using microwave radiation to induce exfoliation of a semiconductor layer from a donor substrate. The donor substrate may be implanted, bonded to a carrier substrate, and heated via the microwave radiation. The implanted portion of the donor substrate may include increased damage and/or dipoles (relative to non-implanted portions of the donor substrate), which more readily absorb microwave radiation. Consequently, by using microwave radiation, an exfoliation time may be reduced to 12 seconds or less. In addition, a presented method also includes the use of focused ion beam implantation to achieve a pattern-less transfer of a semiconductor layer onto a carrier substrate.

### CROSS-REFERENCE TO RELATED APPLICATIONS

The present application claims priority to the following US filed provisional patent applications: U.S. Ser. No. 60/700,567 filed Jul. 19, 2005 and U.S. Ser. No. 60/698,309 filed Jul. 12, 2005 which are incorporated herein by reference.

### GOVERNMENT RIGHTS

The invention described herein was made with government support under the following grant number, DMR-0308127 awarded by the National Science Foundation. The United States Government may have certain rights in the invention.

### FIELD

The invention relates to the field of semiconductor layer transfer, and more particular to a method of exfoliating semiconductor layers using ion implantation, substrate bonding, and substrate heating.

### BACKGROUND

There are a variety of available processes for making heterogeneous structures and devices. Of particular interest are those processes which are available for building devices in heterogeneous systems as in silicon on insulator (SOI) technology. In addition, with the recent increased interest in flexible electronics and flexible displays, much attention has also been directed to forming novel heterostructures for these applications.

One such process, back etch silicon on insulator (BESOI) technology, involves the etching away of hundreds of microns of material in order to result in a thin layer of silicon on an insulator. This process results in the waste of most of the donor substrate and undesirable total thickness variations in the donor layer surface.

A second process, ion cut technology, involves a process that comprises implanting ions into a donor substrate and using an anneal to exfoliate a semiconductor layer from the donor substrate onto a carrier substrate. In certain examples, an implant-impeding film, which may or may not be photo sensitive, is deposited prior to the implantation step, and determines which portions of the carrier substrate are to receive a transferred semiconductor layer. A variation on the ion cut process involves a process of exfoliating the entire implanted layer, followed by etching away material not wanted.

In comparison to the BESOI technology, the ion cut process tends toward shorter process times due to the reduction in process steps as well as lower levels of material inputs inasmuch as the ion cut process allows for the multiple iterations of reuse of the same donor substrate material.

### SUMMARY

Despite these advantages, there remain a number of technical limitations of the processing schemes. Present techniques rely on resistance heating until an average temperature is reached, which is typically about 400° C. Furthermore, the reaction itself is not usually observed, and thus determination of required processing times is difficult. To overcome this, the prior art guesses the processing time, to ensure process completion. Furthermore, the processing times are typically very long. The high temperatures in conjunction with the long processing times are not well suited to thermally mismatched materials, and restrict the technology to silicon-based structures and materials, and certain III-V compound semiconductor materials compatible with the high processing temperatures.

Furthermore, while the ion cut technology provides some superior characteristics relative to the BESOI technology, both processes have edge profiles which can be improved upon. Edge profile problems in the existing technologies are caused by dosage variations in the implant species due to the impeding film barrier, and can be compounded by overexposure and underexposure of the implant impeding layer in the case of photosensitive films. In addition, both the BESOI and ion cut technologies are vulnerable during the post-etch process to over-etching, which may result in shorting of a transistor, and under-etching, which results in poor device performance.

Therefore, a method of ion cleaving is presented. The presented method comprises an ion cut process that includes using microwave radiation to induce exfoliation of a semiconductor layer from a donor substrate and/or using focused ion beam (FIB) implantation to selectively transfer a portion of the semiconductor layer.

An exemplary method includes providing a donor substrate comprising an implanted region and using microwave radiation to heat a volume of the donor substrate. In one example the volume of the donor substrate includes at least a portion of the ion implanted region, which may be tailored to create a desired cleavage plane within the donor substrate. In such an example, when the microwave radiation is applied to the volume, a semiconductor layer exfoliates from the donor substrate at the cleavage plane. In a further example, a power and/or a frequency associated with the microwave radiation may be tuned in order to increase absorption efficiency within the volume of the donor substrate and/or to establish an exfoliation time. In one example, the exfoliation time may be at least as low 12 seconds, which may be up to a 33% reduction compared to traditional exfoliation using co-implantation or non-co-implantation.

Another exemplary method may also include implanting ionic species into the donor substrate (e.g., hydrogen, helium, and co-implant species such as boron, phosphorous, etc.). The implanted species establish the implanted region. The implanted region may be further tailored to promote microwave power absorption. When the ions are implanted, they may induce damage in the donor substrate. The cleavage plane may be located in regions of high damage density, which may be correlative with the implant depth, R_{P}, into the donor substrate. Alternatively or additionally, the cleavage plane may also be attributed to complex dipoles created by the implanted species. Because the implant may induce radiation damage within the donor substrate, the method may also include performing an anneal or a cycle of anneals.

An exemplary method may further include bonding a carrier substrate to the donor substrates together. When the microwave radiation is applied, the donor substrate may transfer onto the carrier substrate. Any suitable carrier substrate may be used. In a non-limiting example, the carrier substrate may include a semiconductor substrate, dielectric layer, a polymer, and a metal. The donor substrate, on the other hand, may include a micro-electronic material such as silicon, silicon germanium (SiGe), a SiGe alloy, a substrate, a III-V alloy, a II-VI substrate, or a II-VI alloy.

An alternative method is described that may be used to induce selective exfoliation of a portion of the donor substrate. The exemplary method includes providing a donor substrate, using focused ion beam (FIB) implantation to co-implant a portion of the donor substrate, and heating the donor substrate to induce exfoliation of the portion of the semiconductor layer. Prior to or after the co-implant, the donor substrate may receive a background implant of elemental species, such as hydrogen or helium. The co-implant species may include boron, or other suitable co-implant species. After the co-implant, the donor substrate may be heated using a variety of techniques, such as microwave induced exfoliation, rapid thermal anneal or resistive heating. In particular, the exfoliation time of the portion of the donor substrate is reduced relative to an exfoliation time associated with non-co-implanted portions of the donor substrate. As an example, the exfoliation time for a co-implanted portion is reduced to about 3% of the time required for exfoliation of a non-co-implanted portion, a 97% reduction in processing time.

By choosing an appropriate exfoliation time (i.e., via co-implant dose), the non-co-implanted portions of the donor substrate are not exfoliated, thus enabling selective exfoliation. Consequently, because the co-implant is carried out via FIB implantation, a masking layer may not be needed to inhibit a portion of the co-implantation. Furthermore, the FIB may be guided so as to determine an appropriate patterning of the donor substrate, where only the FIB patterned portion of the donor substrate is exfoliated when the donor substrate is heated.

The exemplary method may also include a bonding process for bonding a donor substrate to a carrier substrate. When the donor and/or carrier substrates are heated, the co-implanted portion of the semiconductor layer may be transferred onto the carrier substrate.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Certain examples are described below in conjunction with the appended drawing figures, wherein like reference numerals refer to like elements in the various figures, and wherein:

FIG. 1A is a block diagram of a partial un-patterned and cleaved cross-section taken from a wafer, according to an example;

FIG. 1B is a block diagram of a partial patterned and cleaved cross-section taken from a wafer, according to an example;

FIG. 2 is a flow diagram of an example method of ion cleaving using microwave induced exfoliation;

FIG. 3 is a flow diagram of an example method of selective ion cleaving;

FIG. 4 is a partial block diagram showing a donor substrate comprising a co-implant region, according to an example;

FIG. 5 is a block diagram showing a donor substrate comprising a patterned co-implant region carried out via a masking layer, according to an example;

FIG. 6 is a block diagram showing a donor substrate comprising a patterned co-implant region carried out via FIB implantation, according to an example;

FIG. 7 is a block diagram shows donor and carrier substrates prepared for bonding, according to an example;

FIG. 8 is a block diagram showing a donor substrate bonded to a carrier substrate, according to an example;

FIG. 9 is a block diagram showing an exfoliated semiconductor layer that has been transferred onto a carrier substrate, according to an example;

FIG. 10 is a graph showing Rutherford backscattering spectra (RBS) obtained from random and channeled orientations of a transferred semiconductor layer, according to an example; and

FIG. 11 is a graph showing micro-roughness of an exfoliated semiconductor layer, according to an example.

### DETAILED DESCRIPTION

### a) Example Cleaved Substrates

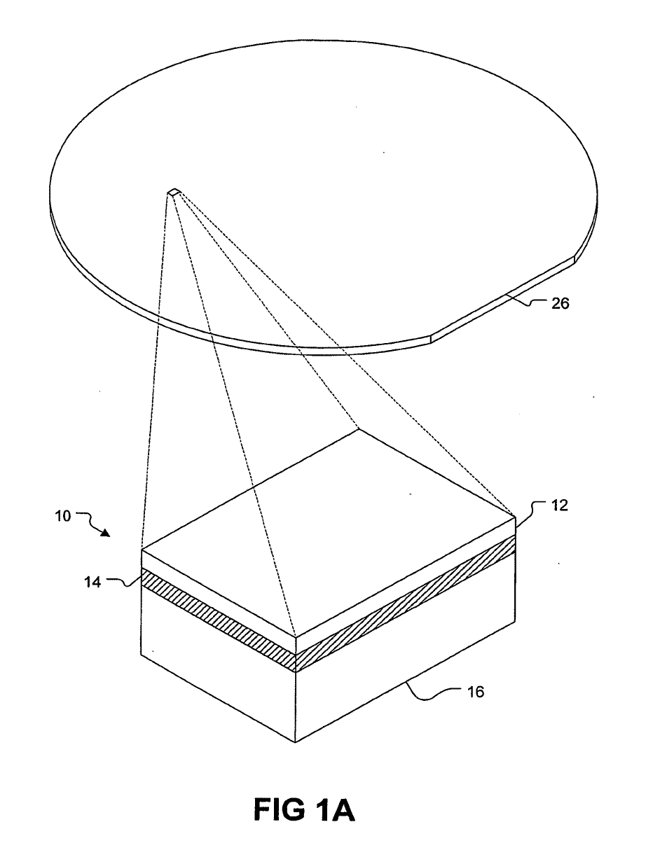

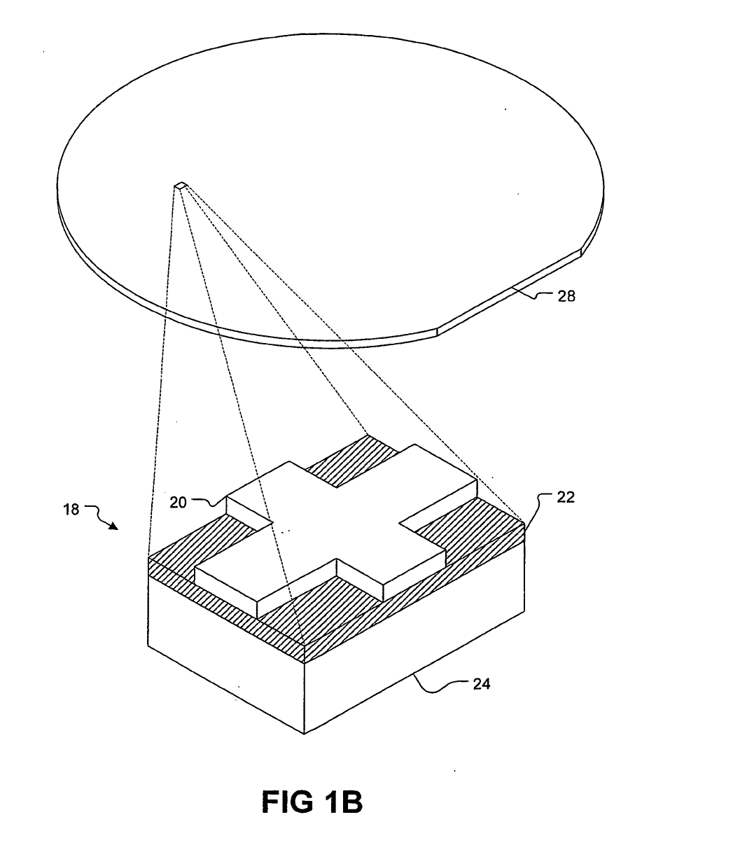

Turning now to the Figures, FIG. 1A is a partial block diagram of an ion cleaved section 10 that may be produced using a method of ion cleaving, which will be described below. The cleaved section 10 includes a semiconductor layer 12, a dielectric layer 14, and a carrier substrate 16. The dielectric layer 14 is interposed between the semiconductor layer 12 and the carrier substrate 16. The cleaved section 10 may be used in a variety of micro-electronic and micro-electronic mechanical (MEMS) devices. In particular, such devices may be fabricated in the semi-conductor layer 12. By being fabricated in the semiconductor layer 12, devices formed in the semiconductor layer 12 may be electrically isolated from the carrier substrate 16 via the dielectric layer 14.

FIG. 1B shows a partial block diagram of a patterned and ion cleaved section 18, which is fabricated according to a method of selective ion cleaving described below. The cleaved section 18 includes a patterned-semiconductor layer 20, dielectric layer 22, and a carrier substrate 24. The dielectric layer 22 is interposed between the semiconductor layer 20 and the carrier substrate 24. Similar to the cleaved section 10, the cleaved substrate 18 may also be used in a variety of micro-electronic and MEMS applications.

In FIGS. 1A and 1B, the cleaved substrates 10, 18 are shown as cross sections respectively taken from a wafer 26 and a wafer 28. It should be understood that the cleaved sections 10, 18 may take on a variety of shapes and sizes and may be included in a variety of configurations. For example, either of the cleaved sections 10, 18 may be included in a variety of flexible electronics and flexible displays. Generally speaking, the carrier substrates 16, 24 are thicker than shown in FIGS. 1A and 113 (relative to the dielectric and semiconductor layers). As an example, the semiconductor layers 12, 20 may comprise thicknesses ranging from 50 nm to 100 μm; the dielectric layers 14, 22 may comprise thicknesses ranging from 80 nm to 3 μm; and the carrier substrate may comprise thicknesses ranging from thicknesses of 1 μm and greater. It should be understood, however, that other thicknesses are possible.

The cleaved section 10, 18, may also comprise a variety of different materials. For example, the semiconductor layers 12, 20 may be supplied from a donor substrate which is a microelectronic material such as silicon (crystalline and amorphous), silicon germanium (SiGe), a SiGe alloy, a III-V material, a III-V alloy, a II-VI substrate, and a II-VI alloy. The carrier substrate may include a structural material such a semiconductor substrate, polymer, a dielectric, and a metal. A semiconductor substrate, for example, may comprise bulk silicon. In some examples, the dielectric layers 14, 22 may comprise a variety of electrically-insulative materials or other materials that facilitate the bonding of a donor substrate to a carrier substrate. In an alternative example, the dielectric layers 14, 22 may not be included. In such an example, the carrier substrate 16 would be directly bonded to the semiconductor layer 12 and the carrier substrate 24 would be directly bonded to the semiconductor layer 20.

### b) Cleaving Via Microwave Radiation

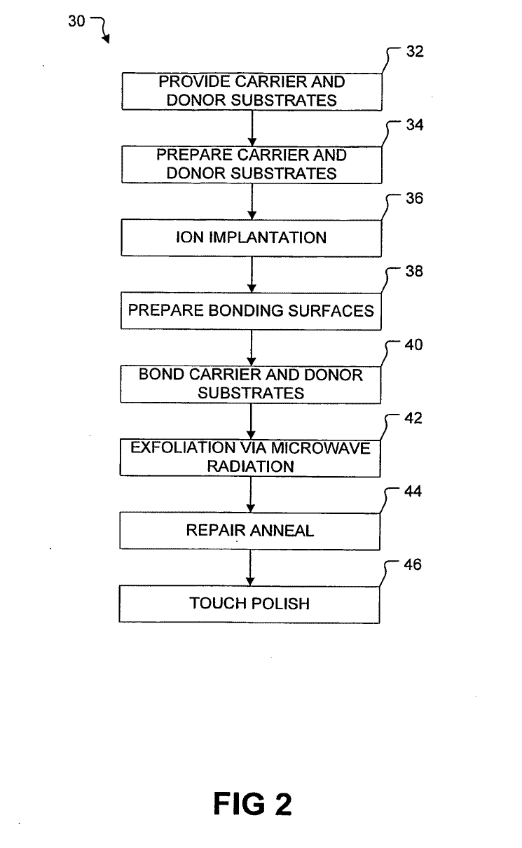

FIG. 2 shows an example method 30 for ion cleaving using microwave radiation. At block 32, carrier and donor substrates are provided. At block 34, both of the carrier and donor substrates are prepared for ion implantation. Such preparation may involve a wet and/or dry chemical clean or any other suitable process for preparing the surface of each of the substrates. In addition, the carrier and donor preparation may also include depositing an oxide layer or similar layer for screening the implantation. Furthermore, if a co-implant is to be carried out (described below) preparation may also include patterning a mask layer, such as a hard mask (e.g., silicon dioxide, silicon nitride, etc.) or a photo-resist mask.

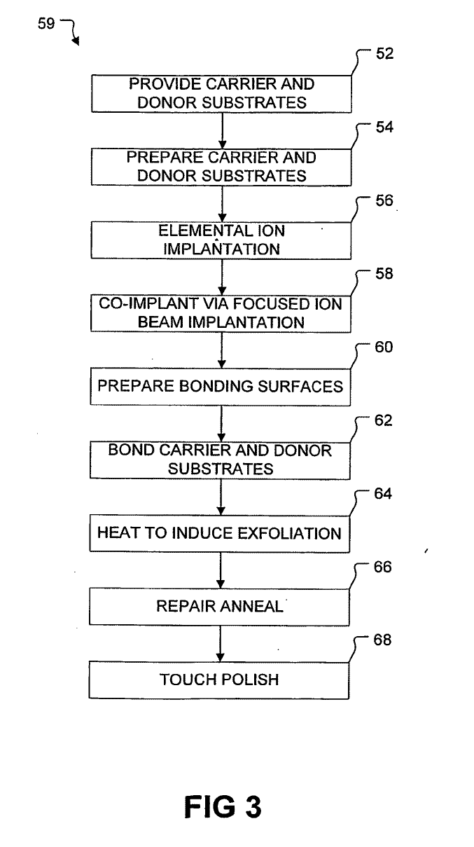

At block 36, ion implantation is carried out in order to create an implanted region within the donor substrate. The ion implant may comprise implanting elemental ionic species into the donor wafer or co-implanting both elemental species and co-implant species into the donor wafer. A co-implant, which will be described in more detail with reference to FIG. 3, may be used, for example, to increase exfoliation time or reduce exfoliation temperature. Elemental species include ionized hydrogen (H) or helium (He). Co-implant species include ionized boron (B), phosphorous (P), arsenic (As), antimony (Sb), silicon (Si), and/or germanium (Ge).

The implant energy and dose may be selected so as to establish an implant depth (R_{P}) within the donor substrate. The average implant depth and implant species density are correlative with a depth associated with a cleavage plane within the implanted region. The cleavage plane may be attributed to damage associated with the implant, the locations of the implanted species, or a combination of both the damage and the implanted species. Generally speaking, the deeper the implant is the deeper the cleavage plane will be; and, as the density of the implanted species increases so will the likelihood of inducing a cleavage plane substantially near the implantation depth. Due to the nature of the implantation, the cleavage plane is congruent throughout, having a similar depth at any measured point.

At block 38, both the carrier and donor substrates are prepared for wafer bonding. The bonding surface preparation may involve cleaning the donor substrate, removing damaged/native oxide, and depositing or growing an oxide on the surface of both substrates. The type of bonding preparation may depend on the type of bonding that is carried out (e.g., fusion bonding, plasma activated bonding, and anodic/field assisted bonding). For example in fusion bonding, the surfaces of each of the carrier and donor substrates may be wetted with DI water. On the other hand, in plasma activated boding the surfaces of the carrier and donor substrates may be treated with an oxygen plasma.

Once the bonding surfaces are prepared, the carrier and donor substrates are bonded, shown at block 40. The block 40, for example, may be carried out using fusion bonding, where pressure along with a subsequent anneal may bond the carrier and donor substrates together. In another example, plasma activated bonding may be employed, which uses a lower anneal temperature than fusion bonding. Alternatively, field assisted bonding may be carried out using both an anneal and a voltage applied across both the carrier and donor substrate. Other bonding processes are also possible.

At block 42, the bonded carrier and donor substrates are exposed to microwave radiation to induce exfoliation of a semiconductor layer from the donor substrate onto the carrier substrate. Unlike traditional heating, implanted species involved in the ion cutting serve to increase the rapid heating of the donor substrate. The ion-induced damage in the donor substrate increases absorption of microwave radiation. In addition, the implanted ions also create complex dipoles within the implanted region, which may also increase microwave power absorption. This may be a significant and beneficial side effect of creating radiation damage in a donor substrate. Power absorption in microwave heating is volumetric and is directly proportional to the sample's dielectric loss and ionic conduction.

The undamaged and the un-implanted region of the donor substrate also absorb microwave power volumetrically, increasing damage and platelet size in the ion-cut region from within the donor substrate. It is also contemplated that the damaged/ion implanted region of the donor substrate may contribute to thermal conduction throughout the donor substrate, which radiates away from the damaged/ion implanted region. In general, the increased local power absorption combined with volumetric heating is a mechanism that shortens the incubation time in the case of microwave heating, as compared with traditional ion-cut heating processes. As an example, the exfoliation time may be at least as low 12 seconds, which may be up to a 33% reduction compared to traditional exfoliation using co-implantation or non-co-implantation.

The microwave power induces a heat within a volume of the donor substrate, which causes a semiconductor layer to exfoliate from the donor substrate due to the tremendous partial pressures exerted by the species previously implanted within the donor substrate. The volume, for example, may comprise a portion of the implanted region. Additionally or alternatively, in order to induce exfoliation, the volume may comprise any portion of the donor and/or carrier substrate. As described above, the thickness of the semiconductor layer may be established by a cleavage plane within the implanted region. The power and frequency of the microwave radiation may be appropriately tuned in order to create a desired exfoliation process. For example, increasing at least one of the power and the frequency of the radiation may decrease the time associated with exfoliation the semiconductor layer. In such an example, the microwave radiation may have a frequency within a range of about 1 to 300 GHz and a power of 1 kW or more.

After the exfoliation of the semiconductor layer, the semiconductor layer undergoes an anneal, or a cycle of anneals, which may be used to repair radiation damage and to out-diffuse implant and/or co-implant species from the semiconductor layer. Block 44 shows such a repair anneal. At block 46, the semiconductor layer may also undergo a touch polish, via a chemical-mechanical-polish, for example. The touch polish may be used to further remove radiation damage/and or to increase uniformity of the semiconductor layer.

### c) Selective Ion Cleaving

FIG. 3 shows an example method 50 for selectively cleaving a semiconductor substrate. The method 50 comprises many of the processes that the method 30 comprises. For example, the method 50 comprises blocks 52 and 54, which convey both carrier and donor substrate provision and preparation. However, the method 50 also includes a co-implant process, shown at block 56 and 58. At the block 56, elemental ion species are implanted into the donor substrate. At the block 58, co-implant species are selectively implanted into the donor wafer via FIB implantation. By using a FIB implantation to selectively implant co-implant species into the donor substrate, a pattern may be created. In particular, the pattern may be created without the use of a masking layer.

It should be understood that many types of FIB systems may be used to co-implant the donor substrate. In general, however, a FIB system will comprise a plasma source and at least two electrodes. The first electrode is at a first voltage potential that is used to draws ions out of the plasma. The second electrode is at a second voltage potential that is much higher than the first voltage potential. The preferred FIB voltage across the first and second electrodes is between approximately 75 kV and 250 kV. Once ions are drawn out of the plasma there are accelerated through the field established by the two electrodes. The second electrode has an aperture, which is used to focus a spot size associated with the beam of ions exiting the second electrode. The preferred FIB spot-size is between approximately 50 nm and 100 nm. In general, an assembly that comprises the first and the second electrodes is referred to as an ion gun.

The donor substrate may be mounted on a stage that is rastered across the ion beam. The stage may be coupled to a servo, which is in turn coupled to a microcontroller. The microcontroller may be programmed to run a routine that establishes a co-implant pattern within the donor substrate. In an example, if the donor substrate comprises silicon, it is preferable that co-implant species comprise boron, so as to adequately exfoliate the co-implanted portion of the donor substrate before the non-co-implanted portion exfoliates. However, it is contemplated that a co-implant of other types of co-implanted species may be tailored to achieve a desired exfoliation.

Advantageously, using a FIB implantation for co-implantation provides a pattern-less transfer of a semiconductor layer or other type of thin film using the ion cut process, which may be carried out at nanometer scale resolution. This pattern-less transfer may also improve the speed of processing traditional ion cut materials. In addition, pattern-less co-implantation may improve the edge profile of transferred materials and may also elimination post-etch processing that is normally associated with conventional photo-resist masking and etching. Furthermore, FIB based co-implantation may also overcome current limits on device performance of structures produced using the ion cut process. For example, improved edge resolution allows transistors with improved operating speeds and packing densities. Improvements in these areas may result in the potential for the use of ion cut processing for flat panel displays.

Next, after co-implantation, the carrier and donor substrate may be prepared for bonding and then bonded together, respectively shown at blocks 60 and 62. As described above, the bonding preparation and bonding may be carried out in a variety of ways.

At block 64, the donor and carrier substrates may be heated to induce exfoliation. The exfoliation process may be carried out using conventional annealing, a rapid thermal anneal, resistive heating, or the microwave induced exfoliation described above. When the donor substrate is heated, the co-implanted region of the donor substrate will exfoliate at a faster rate than non-co-implanted regions of the donor substrate. Consequently, layer transfer occurs in desirable areas only—a process which accomplishes the same result, with less processing, as etching away any undesirable area of the transferred layer. For example, the heating time in co-implanted portions regions may be approximately 3% of the time that is needed for non-co-implanted portions to exfoliate. Such a reduction creates a large processing window by which the donor and carrier substrates may be heated without the risk of exfoliating materials in unwanted areas. After the layer transfer, the rest of the donor substrate may be reused, or discarded. Shown respectively at blocks 66 and 68, the transferred semiconductor layer may also be subsequently annealed and touch polished.

### d) Silicon-Based Microwave Induced Ion Cleaving Data

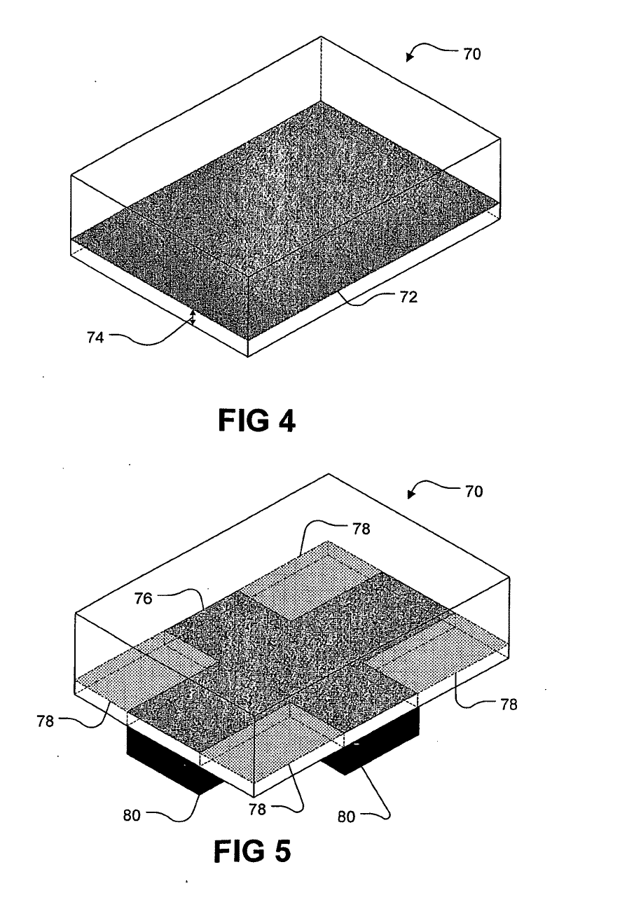

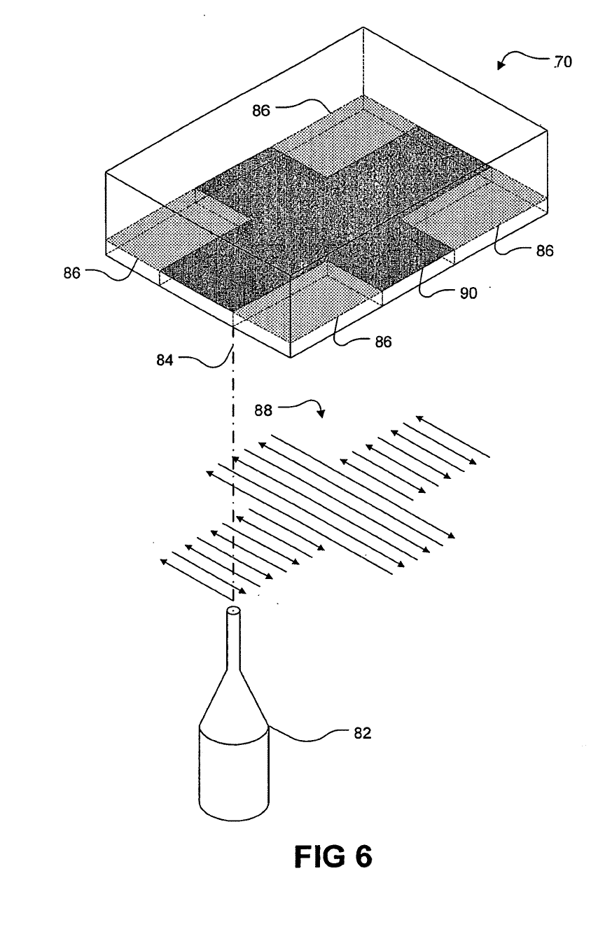

Described below is experimental data related to microwave induced ion cleaving. To illustratively depict microwave induced exfoliation, the experimental data and processing conditions are associated with the block diagrams of FIGS. 4 and 7-9. In particular, these block diagrams show a donor substrate at various points of processing. In addition, the FIGS. 5-6 are prophetic examples, which show block diagrams that correspond to patterned-co-implanted portions of a donor substrate.

Microwave induced exfoliation was carried out on donor and carrier substrates that comprised Czochralski-grown P-type boron-doped 1-13 Ωcm (100) oriented silicon. The donor substrate was cleaned using a Radio Corporation of America (RCA) clean and was placed in an Varion/Extrion Division 200-DF4 ion implanter and implanted with 0-3×10¹⁵/cm², 175 keV boron (B+) ions, and 9×10¹⁶/cm²-1×10¹⁷/cm², 50 keV hydrogen (H+) ions at room temperature. FIG. 4 shows a donor substrate 70 having an implanted region 72, which corresponds to the co-implanted hydrogen and boron doped region. It should be understood, however, that co-implantation is not necessary for microwave induced exfoliation. Further, an implantation depth 74, may be tailored to achieve a desired cleave plane within the donor substrate.

In addition, although not carried out in this experiment, a co-implant may alternatively be carried out using a mask layer, achieving a desired patterning of an exfoliated semiconductor layer. FIG. 5, for example, shows the donor substrate 70 having a co-implanted region 76 and a non-co-implanted region 78. The co-implanted region may be created using a masking layer 80 that could be present during co-implantation of the donor substrate 70.

Alternatively, and according to the method 50 described above, FIB implantation may be used for co-implantation. FIG. 6 shows a block diagram illustrating FIB implantation of the donor substrate 70. An ion gun 82 may be used to provide an ion beam 84, which injects co-implant species into the donor substrate 70. The carrier substrate 70 may include an implanted region 86 that comprises elemental species such as hydrogen or helium. The electron gun 82 or a stage (not shown) holding the donor substrate 70 may be rastered according to a raster pattern 88. As the ion beam 84 is rastered, a co-implant region 90 may be formed in the donor substrate 70 without the use of a mask layer.

Returning to the experimental data, the implanted donor substrate and non-implanted carrier substrates were coated with a chemically grown oxide, which was then RCA cleaned and placed in a Tegal asher at 100° C. for plasma surface activation using a 300 W, 13.56 MHz, 0.3 SCFH oxygen RF plasma. After plasma activation, rinsing, and spin drying, the donor and carrier substrates were placed in surface-to-surface contact at room temperature. The bonded pairs were subsequently annealed in a mechanical furnace at 100° C. for 2 hours to drive out any residual water at the bond interface. FIG. 7 shows the donor substrate 70 coated with an oxide 92 and a carrier substrate 94 coated with an oxide 96.

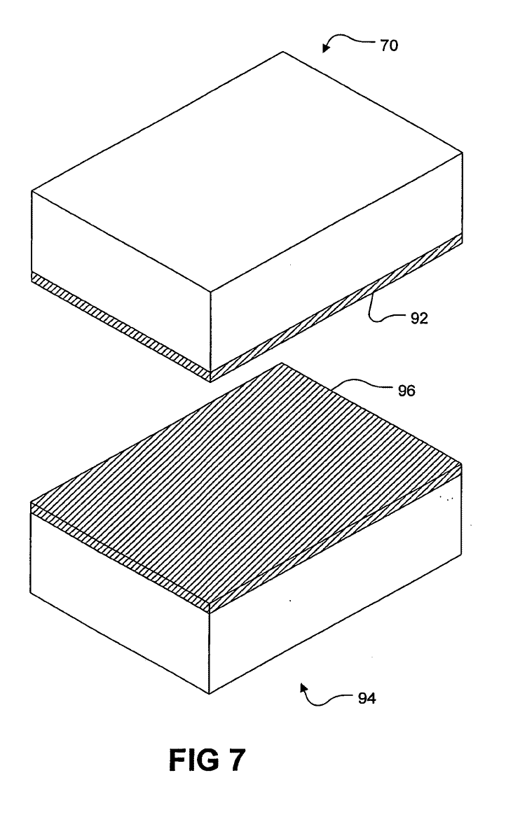

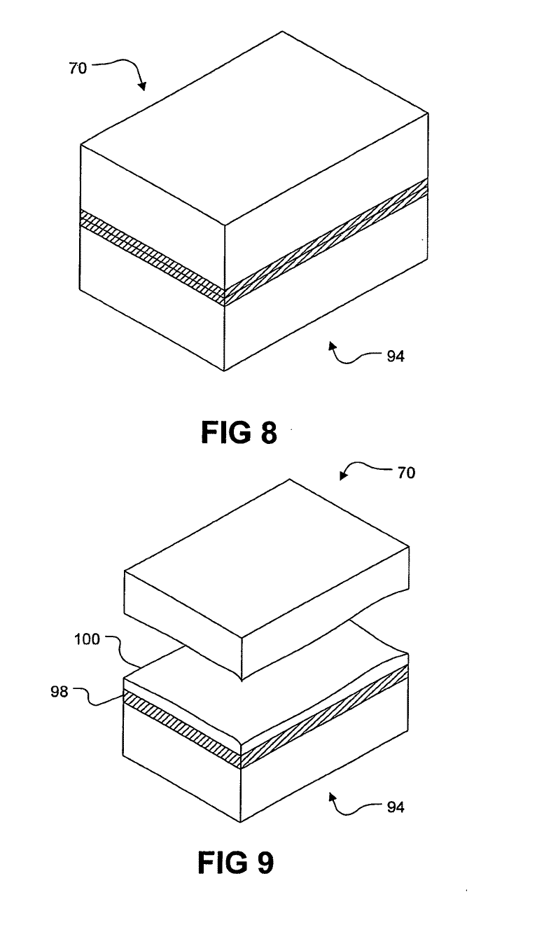

After the furnace anneal, the bonded donor and carrier substrates were placed in a 2.45 GHz 1300 W cavity applicator microwave system. As an example, FIG. 8 shows the donor substrate 70 bonded to the carrier substrate 94.

Various bonded substrates were then evaluated, where microwave exposure times varied for time durations ranging from 12 seconds to 1.5 minutes before layer transfer was visually observed. FIG. 9 shows the donor substrate 70 after microwave induced exfoliation. The carrier substrate includes a bonded oxide 98 and a transferred semiconductor layer 100.

During processing, temperature profiles were monitored using a Raytek Compact MID series pyrometer. The resulting surface quality of transferred films was characterized using a Nanoscope IIIE atomic force microscope in tapping mode in order to determine the root mean square (RMS) roughness of the transferred layer. Rutherford backscattering (RBS) in both random and channeled orientations was performed using a 1.7 MV tandem accelerator. RUMP software (a Rutherford backscattering spectroscopy analysis package) was used to simulate layer thicknesses and to evaluate the crystallinity of the transferred layer. Hall Effect measurements were obtained to examine the electrical characteristics of the “as exfoliated” samples. Cross-section transmission electron microscopy (XTEM) was performed to examine microstructure and defect behavior in the transferred layers.

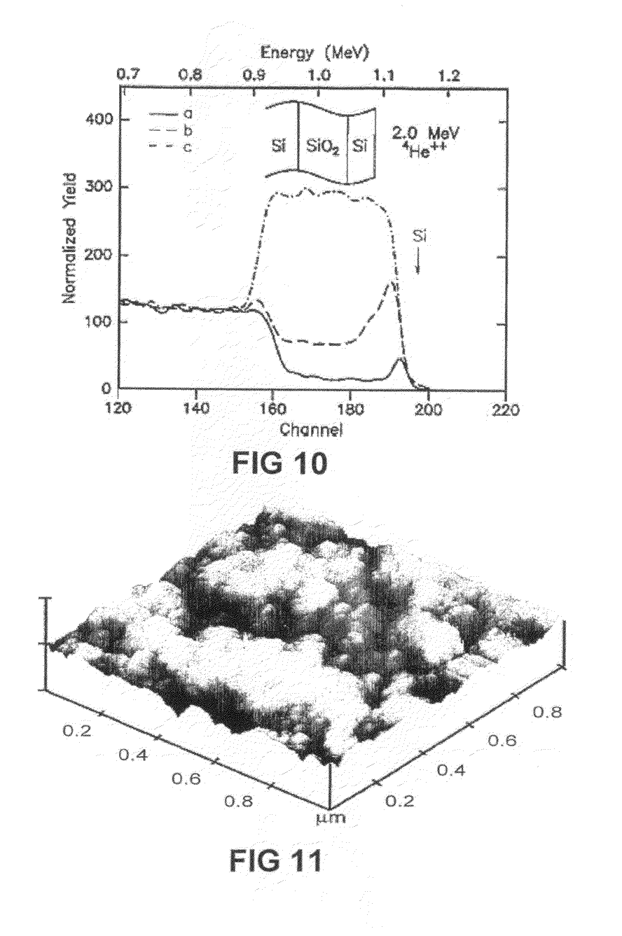

FIG. 10 is a graph showing Rutherford backscattering (RBS) spectra obtained from random and channeled orientations of a typical transferred layer. Data is given for (a)<100> aligned scattering from the transferred layer after damage repair by vacuum furnace annealing, (b)<100> aligned scattering from the transferred layer as cut, with no additional annealing, and (c) random non-aligned scattering from the as cut layer. Spectra from the transferred layer in both random and channeled orientations demonstrate that the ion-cut process is successful in using microwaves to initiate the exfoliation of single crystal silicon. RUMP simulation of the RBS spectra (c) determine the thickness of the transferred layer to be 4700 angstroms, and that of the oxide layer 7250 angstroms. Transport of ions in matter (TRIM) calculations demonstrate that the thickness of the exfoliated layer correlates well with the peak in the radiation damage caused by implantation, and not the projected ranges of the implant species.

Projected ranges for the boron and hydrogen implants used in FIG. 10, determined using TRIM calculations, were approximately 5120 angstroms and 4520 angstroms, respectively. An “as cut” sample in random orientation, spectrum (c), demonstrates a continuous layer of silicon deposited on the insulator; while also hinting at a mild surface micro-roughness as evident in the width of the low energy edge at channels 150-160. The dramatic decrease in yield for spectrum (b), an (100) aligned sample of “as cut” SOI, demonstrates that the transferred layers keep their crystallinity. The width of the surface peak in the “as cut” channeled spectrum (b) indicates that the majority of the radiation damage is concentrated at the top of the transferred layer. As can be seen when comparing channeled spectrum (a), obtained from an annealed transferred layer, and channeled spectrum (b), obtained from the as cut transferred layer, most of the radiation damage is repaired upon further annealing of the microwave initiated ion-cut samples.

FIG. 11 is a graph showing the micro-roughness, measured using atomic force microscopy, of the surface of a typical transferred layer. The root mean square (RMS) roughness of the sample averages approximately 5.25 nm. Depending on implantation parameters, incubation times, and anneal temperatures, previously documented micro-roughnesses varies between approximately 3.4 nm and 10 nm over one micron sampling distances.

Table 1 displays changes in resistivity, dominant carrier species, carrier concentration, and electronic mobility, measured using Hall Effect electrical measurements, as a function of anneal temperature and time for successive high temperature anneals of a microwave-initiated exfoliated layer. The donor substrate was implanted with approximately 9×101⁶ H⁺ ions/cm² at an implant voltage of 50 keV, and 2×10¹⁴ B⁺ ions/cm² at an implant voltage of 175 keV. Sheet charge is reported since the damage layer thickness is not known exactly. The layer thickness can be estimated as approximately twice the implant depth normal to the surface (Rp), which is approximately 1 μm for this sample.

TABLE 1

| Cate- | | Resistivity | | Concentration | Mobility |
|---|---|---|---|---|---|
| gory | Description | (Ω cm) | Type | (cm⁻³) | (cm²/V s) |
| Donor | As exfoliated | 3.88 | n | 1.3 × 1015 | 57 |
| Si | | | | (cm−2)a | |
| SOI | As exfoliated | 3.83 | n | 5.49 × 1016 | 69 |
| | 500° C., 2 hrs | 4.2 | n | 6.2 × 1016 | 24 |
| | 600° C., 2 hrs | 4 | p | 2.13 × 1017 | 7 |
| | 700° C., 2 hrs | 0.0447 | p | 1.56 × 1018 | 89 |
| | 700° C., 4 hrs | 0.0374 | p | 2.05 × 1018 | 80 |
| | 800° C., 2 hrs | 0.023 | p | 3.32 × 1018 | 82 |

The anneals were performed in order to repair radiation damage in the transferred layer. The high temperature anneals were performed in a vacuum furnace instead of a microwave oven in order to have a common reference point for comparison with traditional ion cut samples. When viewing the data in table 1, most noteworthy is the change in conductivity type, and the annealing temperature where this change takes place. The observed trend compares well with previous work, in which the surface of un-cut samples were p-type, cut sample surfaces were n-type, and upon successive anneals the cut sample surfaces returned to p-type. The change in conductivity type upon exfoliation is due to hydrogen related shallow donors and ion enhanced diffusion of interstitial oxygen giving rise to thermal donors. Published values of p-type mobility in un-etched samples lie in the range between approximately 9 and 121 cm²/V s. However, in traditional ion cut processing, the carrier concentrations of samples measured after anneals above approximately 650° C. were significantly lower (˜10¹⁶/cm³-10¹⁷/cm³) than the results attained in this experiment. The change in hole carrier concentration can be explained by electrical activation of some co-implanted boron. The hole mobilities attained in the experiment compare well with mobilities attained in single crystal silicon with broadly the same carrier concentrations.

### e) Conclusion

A variety of examples have been described above. The above description has described a method of ion cleaving using microwave radiation. Also, the description has described a method for selectively ion cleaving via FIB implantation. The experimental data shows that microwave radiation may be used to at least reduce the time associated with exfoliating a semiconductor layer onto a carrier substrate.

Those skilled in the art will understand that changes and modifications may be made to these examples without departing from the true scope and spirit of the present invention, which is defined by the claims. Thus, for example, the experimental data, and processing descriptions presented above may be modified and still achieve a desired exfoliation and/or pattern of a semiconductor layer. In addition, it should be understood that the methods described above may be used to fabricate a variety of devices. For example, it is contemplated that microwave induced exfoliation and/or selective ion cleaving may be particularly suited to the filed of thin film electronics and displays. In particular, the above methods may be used to bond semiconductor materials to a wide variety of carrier substrates, including polymers and other flexible materials.

Finally, the described method should not be viewed as being limited to only being used for fabricating micro-electronic or MEMS devices. It is also contemplated that the presented methods may also be suited to a variety of semiconductor cleaving applications. For example, the described methods may be useful as a defect analysis tool by using microwave radiation to “peel away” semiconductor layers. For instance, in microelectronic failure analysis, a carrier substrate may be bonded to a substrate, the substrate exfoliated, and a semiconductor layer may be transferred and then analyzed. Using microwave radiation in lieu of traditional annealing may reduce transfer time and possibly transfer temperature, allowing defect analysis to be carried out in a controlled and systematic fashion.

Accordingly, the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

We claim:

1. A method for ion cleaving, the method comprising:
providing a donor substrate that includes an implanted region for establishing a cleavage plane within the donor substrate; and
using microwave radiation to heat a volume of the donor substrate to a temperature that induces exfoliation of a semiconductor layer from the donor substrate at the cleavage plane.

2. The method as in claim 1, wherein the volume of the donor substrate comprises at a least a portion of the ion implanted region.

3. The method as in claim 1, further comprising tuning at least one of a power and a frequency associated with the microwave radiation to establish an exfoliation time associated with the exfoliation of the semiconductor layer.

4. The method as in claim 1, wherein the exfoliation time is within a range of about 12 seconds to 1.5 minutes.

5. The method as in claim 1, wherein providing the donor substrate further comprises implanting ionic species into the donor substrate to create the implanted region.

6. The method as in claim 5, wherein the cleavage plane is attributed to damage induced by implanting the ionic species.

7. The method as in claim 5, wherein the ionic species comprise elemental species selected from the group consisting of hydrogen and helium ions.

8. The method as in claim 5, further comprising performing a thermal anneal for repairing radiation damage in the semiconductor layer.

9. The method as in claim 5, further comprising bonding a carrier substrate to the donor substrate, wherein the exfoliation of the semiconductor layer transfers the semiconductor layer onto the carrier substrate.

10. The method as in claim 9, wherein the carrier substrate comprises a structural material selected from the group consisting of a semiconductor substrate, a dielectric, a polymer, and a metal, and wherein the donor substrate comprises a micro-electronic material selected from the group consisting of silicon, silicon germanium (SiGe), a SiGe alloy, a III-V substrate, a III-V alloy, a II-VI substrate, and a II-VI alloy.

11. A method for selective ion cleaving, the method comprising:
providing a donor substrate that includes an implanted region comprising a first implanted species;
using focused ion beam implantation to co-implant a second species into a portion of the implanted region; and
heating the donor substrate to a temperature that induces exfoliation of a patterned semiconductor layer from the portion of the implanted region.

12. The method as in claim 11, wherein the heating of the donor substrate is carried out for an amount of time that is insufficient for exfoliating a non-co-implanted portion of the donor substrate.

13. The method as in claim 11, wherein the co-implantation of the second ionic species is carried out without a masking layer.

14. The method as in claim 11, wherein using the focused ion beam implant to co-implant further comprises directing an ion-beam to create a co-implant pattern, wherein the co-implant pattern comprises the portion of the ion-implanted region.

15. The method as in claim 11, wherein the first implanted species comprise elemental species selected from the group consisting of hydrogen and helium.

16. The method as in claim 11, wherein the second implanted species comprise co-implanted species selected from the group consisting of boron, arsenic, phosphorous, antimony, germanium, and silicon.

17. The method as in claim 11, further comprising bonding a carrier substrate to the donor substrate.

18. The method as in claim 17, wherein the heating of the donor substrate causes the patterned semiconductor to transfer onto the carrier substrate.

19. The method as in claim 17, wherein the carrier substrate comprises a structural material selected from the group consisting of a polymer, a dielectric, a polymer, and a metal, and wherein the donor substrate comprises a micro-electronic material selected from the group consisting of silicon (Si), silicon germanium (SiGe), a SiGe alloy, a III-V substrate, a III-V alloy, a II-VI substrate, and a II-VI alloy.

20. The method as in claim 11, wherein heating the semiconductor layer is carried out using microwave radiation.
